(19) United States
(12) Patent Application Publication
(10) Pub. No.: US 2001/0028721 A1
(43) Pub. Date: Oct. 11, 2001

(54) Control apparatus

(76) Inventor: Michael Paul Stavrou, Mosman (AU)

Correspondence Address: FLYNN, THIEL, BOUTELL & TANIS, P.C., 2026 Rambling Road, Kalamazoo, MI, 49008-1699, US

(21) Appl. No.: 09/808,919

(22) Filed: Mar. 15, 2001

(30) Foreign Application Priority Data
Apr. 11, 2000 (GB) 0008916.9

(51) Int. Cl. H04B 1/00; H03G 3/00

(52) U.S. Cl. 381/124; 381/109; 381/119

(57) ABSTRACT

Control apparatus is described which can be used to vary two parameters such as the base and treble output levels of a sound system. The control apparatus comprises a rotatable knob having two separate zones of differing electrical conductivity. The location of the users fingers on the knob determines which of the parameters will be varied when the knob is rotated.

This application relates to control apparatus, and more particularly to apparatus where at least two parameters may be varied by the operation of a single control device.

In order to increase the number of parameters controlled by the control devices on a control panel, it is generally necessary to increase the number of knobs. This requires either a greater density of control devices, or a larger control panel. This may not be possible if, for example, the control devices are already closely spaced and the available space is limited.

As an alternative, multi-function controllers have been proposed, whereby each controller may vary more than one parameter. The user may toggle the function of a single controller, such as a knob, by selecting buttons, switches, items on a computer screen, or by using some other independent ergonomic activity.

Dual concentric knobs have also been proposed which comprise two concentric, independently rotatable knobs. Each knob is connected to one of two concentric shafts. The shafts are in turn connected to, for example, two stacked potentiometers, or two very expensive and rare dual concentric encoders. Such arrangements may be complex and expensive.

The present invention seeks to mitigate these disadvantages.

According to the invention, there is provided control apparatus for varying at least two parameters, comprising a control part, wherein the location of contact by the user on the control part determines which of the at least two parameters is varied.

Thus, the apparatus can simulate a dual concentric control device, such as a knob, but with a simpler design.

The control part may conveniently comprise a rotatable knob. Thus, where the user grasps the knob determines which parameter is adjusted.

The control part may conveniently comprise at least two surface zones of differing electrical conductivity, with one zone advantageously being metallic. This provides a simple and effective means for determining which zones are in contact with the user's hand.

The control part may conveniently be mounted on a control panel, and the control panel may include a capacitance touch circuit in electrical contact with at least one of the zones.

The control panel may further include software for selecting the parameter to be varied in response to the output from the capacitance touch circuit.

Thus, simple means for toggling the function of the control means are provided.

The location of contact by the user on the control part may be determined using optical means, with the control part having zones responsive to touch using optical means.

The apparatus may be suitable for varying the base and treble output levels of a sound system. Thus the apparatus may include first and second zones such that the base may be varied when the user contacts the first zone, and the treble may be varied when the user contacts the second zone.

For a better understanding of the present invention, specific embodiments will now be described, by way of example, in which:

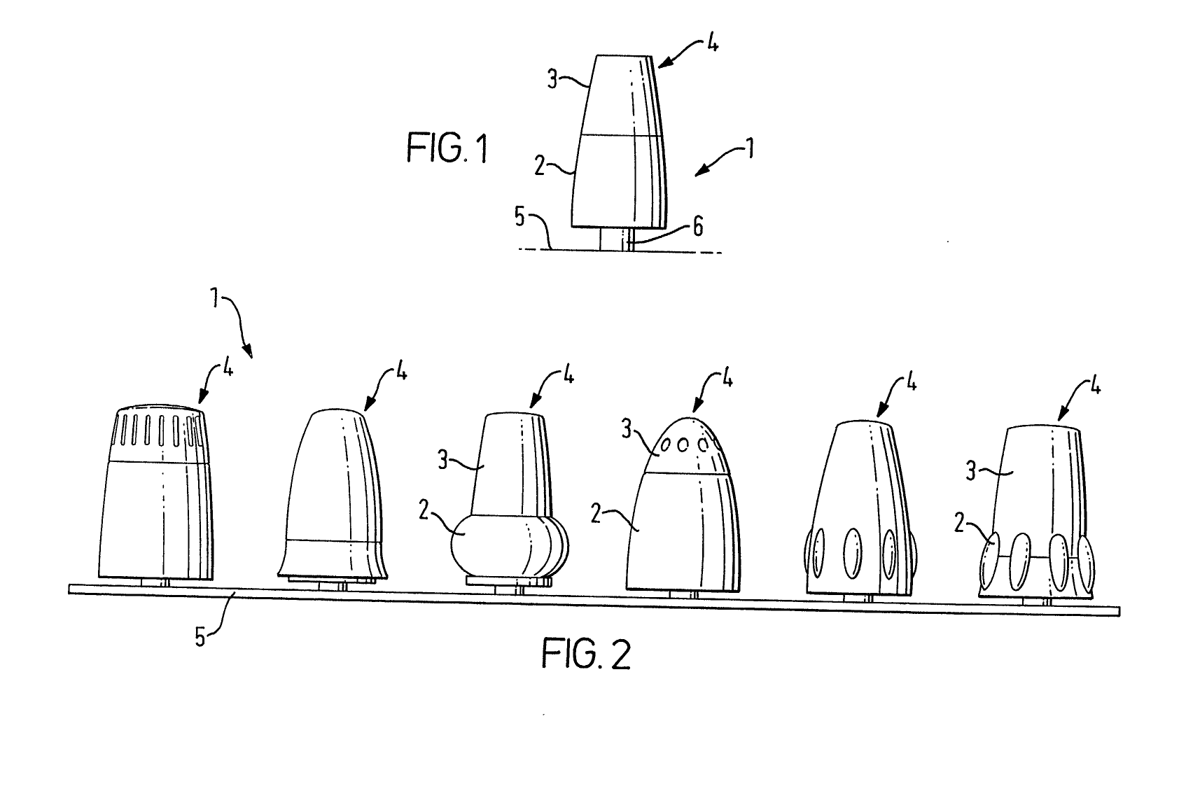

FIG. 1 shows a side view of a first embodiment according to the invention; and

FIG. 2 shows a side view of further embodiments according to the invention.

As shown in FIG. 1, control apparatus 1 for varying at least two parameters, comprises at least two separate zones 2, 3 on control part 4, the arrangement being such that the zone or zones contacted by the user during operation of the apparatus determines which of the parameters is varied. The control part is movable and operable manually by a user, and comprises a rotatable knob 4 in the embodiment shown.

Rotation of the knob 4 while the user's fingers contact the first zone 2 executes control over the parameter mapped to this zone. Rotation of the knob 4 while the user's fingers contacts the second zone 3 will execute control over the parameter mapped to that particular zone.

Thus, the location of the contact by the user determines which parameter is varied when the knob is rotated.

In the specific embodiment, the first and second zones 2, 3 comprise surfaces of differing electrical conductivity. Specifically, the first zone 2 is formed of a metallic layer, whiles the second zone 3 is formed of a layer having a much lower electrical conductivity.

The knob 4 is mounted on a control panel 5, the control panel including a capacitance touch circuit (not shown) in electrical contact with the zones.

In this embodiment, electrical contact is provided through a metallic spring connected to the conventional capacitance touch circuit and pressing on the shaft 6.

In use, the electrical capacitance differential caused by human touch is transferred from the knob to the circuit.

The control apparatus 1 also includes software (not shown) for selecting the parameter to be varied in response to the output from the capacitance touch circuit.

To the operator, each touch sensitive zone on the knob seems to behave as a dedicated controller.

For example, in a sound system turning the knob whilst touching only the first zone 2 might control the treble output level of the sound system. Touching only the second zone 3 of the knob whilst rotating the knob might control the base output level of the sound system.

The first embodiment therefore simulates the operation of a dual concentric knob, with the advantage of having only a single moving part instead of several. This arrangement is advantageous in terms of both simplicity and cost.

The location of the user's fingers on the knob 4 activates the different functions mapped to the different zones. For example, the knob may be connected to a potentiometer, encoder or switch. To the user, the knob with its zones appears as mentioned hereinbefore to be a dedicated controller for a specific function, without the need for operating any further buttons or switches to control the parameter to be varied.

Further embodiments according to the invention are illustrated in FIG. 2. This shows some of the different possible arrangements of the zones. It is understood that the zones may be of any suitable shape or size, as desired.

The control means, which in the specific embodiment is a knob, may have two or more differently touch sensitive surfaces. This sensitivity may be provided either by electrical conductivity as described earlier, or by optical means, or by any other suitable sensor technology. There may be multiple points or levels of touch differentiation provided on the knobs, for varying one or more parameters.

The manually operable control means of the specific embodiment is provided by a rotatable knob, but it is understood that any suitable control means could be provided, for example, a push-in knob or button, or other type of switch.

I claim:

1. Control apparatus for varying at least two parameters, comprising;
(i) a control part;
(ii) at least one contact zone being defined on the control part; and
(iii) wherein the location of contact by the user on the control part determines which of the at least two parameters is varied.

2. Control apparatus as defined in claim 1, wherein the control part comprises a rotatable knob.

3. Control apparatus as defined in claim 1, wherein the control part comprises at least two surface zones of differing electrical conductivity.

4. Control apparatus as defined in claim 3, wherein one of the at least two surface zones is metallic.

5. Control apparatus as defined in claim 1, wherein the location of contact by the user on the control part is determined using optical means.

6. A control panel, comprising control apparatus as defined in claim 1, wherein the control panel further comprises a capacitance touch circuit in electrical contact with at least one of the zones.

7. A control panel as defined in claim 6, wherein the control panel further comprises software for selecting the parameter to be varied in response to the output from the capacitance touch circuit.

8. Apparatus for varying the base and treble output levels of a sound system, comprising control apparatus as defined in claim 1.

9. Apparatus for varying the base and treble output levels of a sound system, wherein there is a control panel as defined in claim 6.
